(19) United States
(12) Patent Application Publication
(10) Pub. No.: US 2010/0128883 A1
(43) Pub. Date: May 27, 2010

(54) System And Method Of Calibrating An Echo Canceller Using Preemptive Tone Sequencing

(76) Inventor: Michael L. Vanderford, Corvallis, OR (US)

Correspondence Address: HEWLETT-PACKARD COMPANY;Intellectual Property Administration, 3404 E. Harmony Road, Mail Stop 35, FORT COLLINS, CO, 80528, US

(21) Appl. No.: 12/597,887

(22) PCT Filed: Apr. 27, 2007
(86) PCT No.: PCT/US07/67667

§ 371 Date: Oct. 27, 2009

(51) Int. Cl. H03B 29/00

(52) U.S. Cl. 381/71.1

(57) ABSTRACT

A system for calibrating an echo canceller using a preemptive tone sequence is provided. The system includes a node and a tone sequence management unit operatively connected to the node. The node includes a speaker, a microphone, and the echo canceller operatively connected to the microphone. The tone sequence management unit transmits a digital tone sequence to the speaker. The speaker plays the digital tone sequence. The microphone records an output of the speaker, converts the output into a digital data segment, and transmits the digital data segment to the echo canceller. The echo canceller is calibrated based on the digital data segment.

### CROSS-REFERENCE TO RELATED APPLICATIONS

This application is related to copending patent application Ser. No. 11/497,886 entitled “System and Method for Managing Virtual Collaboration Systems,” filed on Aug. 2, 2006 and assigned to the same assignee as the present application, the disclosure of which is incorporated herein by reference.

### BACKGROUND

Media conferencing is becoming more commonplace as technological advancements enable the real-time or near real-time transmission of bandwidth-intensive media, such as video and audio, between geographically-dispersed nodes. An exemplary conferencing system may include audio communication between two or more nodes, each utilizing a conference speakerphone or a separate speaker and microphone. One problem that may arise in the conferencing system is echo, which results from the microphone picking up sound from the speaker as the sound reflects off other objects, such as the walls of a room.

A number of echo cancellers have been created to minimize the presence of echo to users. An echo canceller may be initiated and calibrated using an audio input. For example, the echo canceller may be initiated and calibrated as a user begins speaking into a microphone. However, the echo canceller may not properly calibrate if the user's voice is not of sufficient vocal quality, for example, if the user's voice is too low in volume. This is particularly relevant for children, the elderly, sick individuals (e.g., with a cold or flu), and other people with vocal deficiencies. A consequence of an improperly calibrated echo canceller may be that the echo becomes so prevalent that the conference is deemed unusable.

For these and other reasons, there is a need for the present invention.

### SUMMARY

One embodiment provides a system for calibrating an echo canceller using a preemptive tone sequence. The system includes a node and a tone sequence management unit operatively connected to the node. The node includes a speaker, a microphone, and the echo canceller operatively connected to the microphone. The tone sequence management unit transmits a digital tone sequence to the speaker. The speaker plays the digital tone sequence. The microphone records an output of the speaker, converts the output into a digital data segment, and transmits the digital data segment to the echo canceller. The echo canceller is calibrated based on the digital data segment.

### BRIEF DESCRIPTION OF THE DRAWINGS

The accompanying drawings are included to provide a further understanding of the present invention and are incorporated in and constitute a part of this specification. The drawings illustrate the embodiments of the present invention and together with the description serve to explain the principles of the invention. Other embodiments of the present invention and many of the intended advantages of the present invention will be readily appreciated as they become better understood by reference to the following detailed description. The elements of the drawings are not necessarily to scale relative to each other. Like reference numerals designate corresponding similar parts.

FIG. 1 illustrates a block diagram of a system for calibrating an echo canceller using a preemptive tone sequence, in accordance with one embodiment.

FIG. 2 illustrates another block diagram of a system for calibrating an echo canceller using a preemptive tone sequence, in accordance with one embodiment.

FIG. 3 illustrates a flow diagram of a method of calibrating an echo canceller using a preemptive tone sequence, in accordance with one embodiment.

### DETAILED DESCRIPTION

In the following Detailed Description, reference is made to the accompanying drawings which form a part hereof, and in which is shown by way of illustration specific embodiments in which the invention may be practiced. In this regard, directional terminology, such as “top,” “bottom,” “front,” “back,” “leading,” “trailing,” etc., is used with reference to the orientation of the Figure(s) being described. Because components of embodiments of the present invention can be positioned in a number of different orientations, the directional terminology is used for purposes of illustration and is in no way limiting. It is to be understood that other embodiments may be utilized and structural or logical changes may be made without departing from the scope of the present invention. The following detailed description, therefore, is not to be taken in a limiting sense, and the scope of the present invention is defined by the appended claims.

As used herein, the term “media” includes text, audio, video, sounds, images, or other suitable digital data capable of being transmitted over a network.

As used herein, the term “node device” includes processor-based devices, input/output devices, or other suitable devices for facilitating communications among remote users. Examples of node devices include fax machines, video cameras, telephones, printers, scanners, displays, personal computers, microphones, and speakers.

As used herein, the term “node” includes any suitable environment or system configured to transmit and/or receive media via one or more node devices. In one embodiment, the environment is a collaborative environment, which enables remote users to share media across one or more node devices. A collaborative environment will enable, for example, a presenter to simultaneously give a multimedia presentation to an audience not only in the presenter's location but also in one or more remote locations. The collaborative environment may further enable the audience in the remote locations to participate in the presentation as the audience in the presenter's location would participate (e.g., ask questions to the presenter).

As used herein, the term “event” refers to a connection of a plurality of nodes such that one or more node devices of one node are configured to transmit media to and/or receive media from one or more node devices of another node.

Embodiments of a system and method of calibrating an echo canceller using a preemptive tone sequence are described herein. A preemptive tone sequence is played to calibrate the echo canceller at each node. In one embodiment, the preemptive tone sequence is played at the beginning of an event. In one embodiment, the preemptive tone sequence includes a number of consecutive, polyphonic chimes. In one embodiment, different preemptive tone sequences serve as different indicators. For example, a tone sequence may be used to instruct users to begin the event. In one embodiment, the preemptive tone sequence covers a frequency range similar to the frequency range of a human voice.

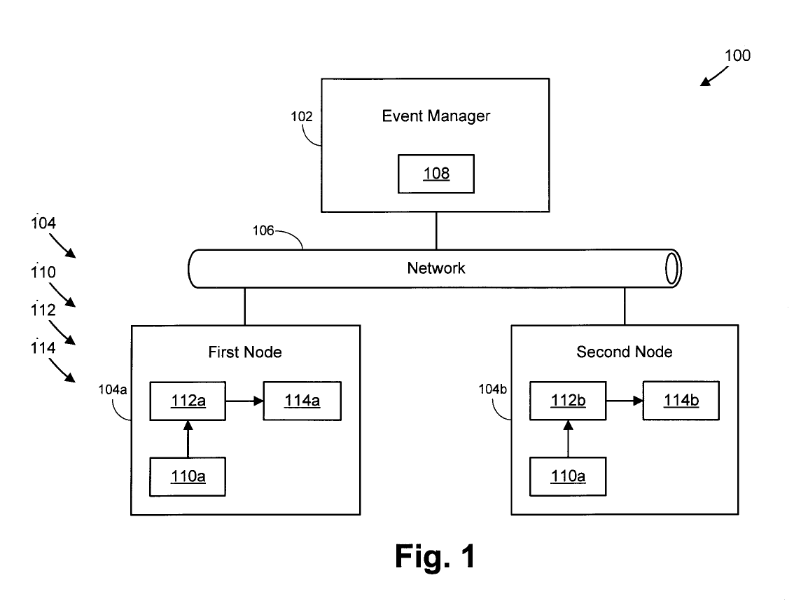

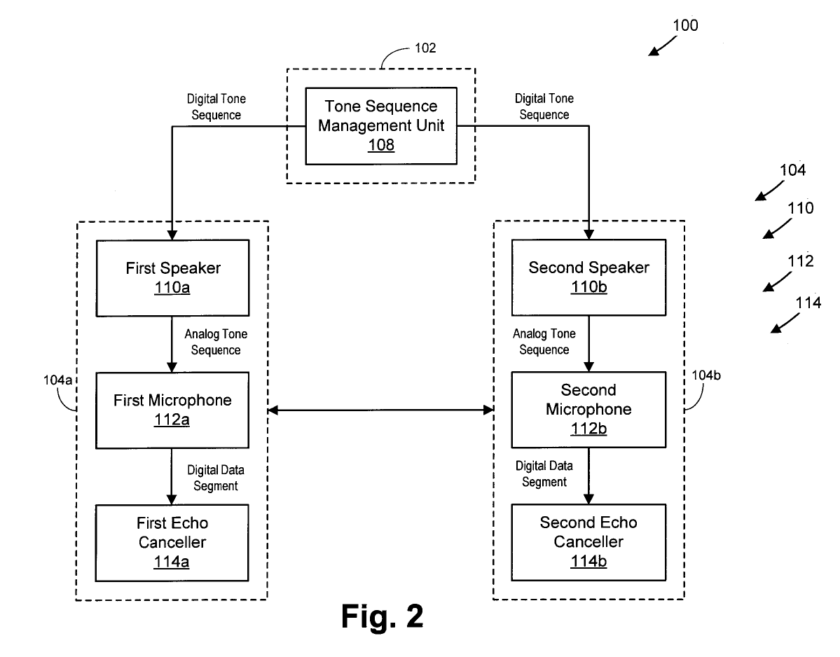

FIG. 1 illustrates a block diagram of a system 100 for calibrating an echo canceller using a preemptive tone sequence, in accordance with one embodiment. FIG. 2 illustrates another block diagram of system 100 for calibrating an echo canceller using a preemptive tone sequence, in accordance with one embodiment. Referring to FIGS. 1 and 2, system 100 includes an event manager 102, a first node 104a, and a second node 104b. Event manager 102 is operatively connected to first node 104a and second node 104b (collectively referred to as nodes 104) via network 106. First node 104a is capable of communicating with second node 104b over network 106. In one embodiment, nodes 104 are geographically-dispersed. Network 106 includes any suitable network, such as a local area network (LAN) or the Internet.

Event manager 102 includes a tone sequence management unit 108. First node 104a includes a first speaker 110a, a first microphone 112a, and a first echo canceller 114a operatively connected to first microphone 112a. Second node 104b includes a second speaker 110b, a second microphone 112b, and a second echo canceller 114b operatively connected to second microphone 112b. Tone management unit 108 transmits a digital tone sequence over network 106 to first speaker 110a and second speaker 110b (collectively referred to as speakers 110). Speakers 110 output an analog tone sequence based on the digital tone sequence.

First microphone 112a and second microphone 112b (collectively referred to as microphones 112) record the analog tone sequence output by speakers 110, convert the analog tone sequence into a digital data segment, and transmit the digital data segment to first echo canceller 114a and second echo canceller 114b (collectively referred to as echo cancellers 114), respectively.

Echo cancellers 114 minimize echo created within nodes 104. Echo cancellers 114 may include any suitable echo canceller capable of minimizing echo in an audio signal. In one embodiment, echo cancellers 114 are initiated after receiving the digital data segment from microphones 112 and are calibrated based on the digital data segment.

In one embodiment, echo cancellers 114 are calibrated by comparing the digital data segment with the digital tone sequence to determine an echo to be eliminated from future recordings of microphones 114. In other embodiments, echo cancellers 114 are calibrated using any suitable process as contemplated by those skilled in the art.

In one embodiment, nodes 104 are enclosed or partially-enclosed rooms, which are capable of creating echo. In one embodiment, microphones 112 are boundary microphones. In one embodiment, speakers 110 that output the analog tone sequence are positioned near microphones 112 such that microphones 112 can effectively record the analog tone sequence. In one embodiment, each corresponding speaker 110 and microphone 112 pair are included within a single unit, such as a speakerphone.

Tone sequence management unit 108 manages one or more tone sequences played by speakers 110. The tone sequence is recorded by microphones 112 and used to calibrate echo cancellers 114. In one embodiment, a tone sequence is a plurality of consecutive, polyphonic chimes. In one embodiment, the plurality of polyphonic chimes are selected based on pleasantly sounding note combinations (i.e., a melody) in accordance with music theory as contemplated by those skilled in the art. In one example, the tone sequence may be created to follow a chord progression.

The tone sequence is of a suitable length and volume, and each chime is of a suitable frequency to properly calibrate echo cancellers 114. In one embodiment, each tone in the tone sequence is about a half-second. In one embodiment, the tone sequence is of a frequency range similar to the frequency range of a human voice. In one embodiment, the tone sequence is of an ascending frequency range. For example, a tone sequence may include a sequence of four audio tones: a 400 Hz tone, a 1000 Hz tone, a 2000 Hz tone, and a 3750 Hz tone. In one embodiment, the delay between each tone is about 500 ms. In other embodiments, the length of each tone, the time between each tone, the volume of the tones, and the melody of the tones are suitably selected for optimal calibration of echo cancellers 114.

In one embodiment, the tone sequence is played by speakers 110 at the beginning of an event (e.g., a teleconference). In one embodiment, the tone sequence is played at the end of an event. In one embodiment, the tone sequence is played when a user joins and/or leaves an event. In other embodiments, the tone sequence is played at any suitable time within the event.

In one embodiment, the tone sequence serves as an indicator, relaying information regarding the event to the users. In one example, the tone sequence may serve as an indicator to begin an event (e.g., to indicate that users may begin speaking). In another example, the tone sequence may serve as an indicator of a user joining or leaving an event. In one embodiment, different tone sequences are used to represent different indicators.

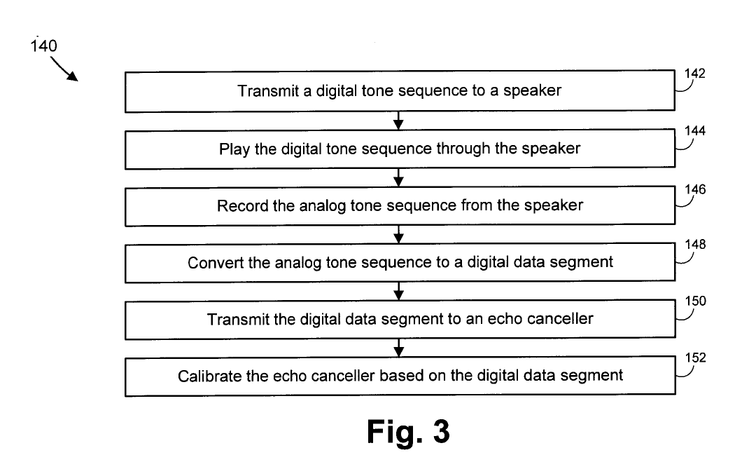

FIG. 3 illustrates a flow diagram of a method 140 of calibrating an echo canceller using a preemptive tone sequence, in accordance with one embodiment. Referring to FIGS. 1, 2 and 3, tone sequence management unit 108 transmits (at 142) a digital tone sequence to speakers 110. As previously described, a tone sequence is a plurality of consecutive, polyphonic chimes. Speakers 110 play (at 144) the digital tone sequence. The digital tone sequence is output from speakers 110 as an analog tone sequence. Microphones 112 record (at 146) the analog tone sequence along with other sounds present in nodes 104. The recorded analog tone sequence is converted (at 148) to a digital data segment, and the digital data segment is transmitted (at 150) to echo cancellers 114. In one embodiment, echo cancellers 114 are initiated after receiving the digital segment. Echo cancellers 114 are calibrated (at 152) based on the digital data segment.

Embodiments described and illustrated with reference to the Figures provide systems and methods of calibrating an echo canceller using a preemptive tone sequence. It is to be understood that not all components and/or steps described and illustrated with reference to the Figures are required for all embodiments. In one embodiment, one or more of the illustrative methods are preferably implemented as an application comprising program instructions that are tangibly embodied on one or more program storage devices (e.g., hard disk, magnetic floppy disk, RAM, ROM, CD ROM, etc.) and executable by any device or machine comprising suitable architecture, such as a general purpose digital computer having a processor, memory, and input/output interfaces.

Although specific embodiments have been illustrated and described herein, it will be appreciated by those of ordinary skill in the art that a variety of alternate and/or equivalent implementations may be substituted for the specific embodiments shown and described without departing from the scope of the present invention. This application is intended to cover any adaptations or variations of the specific embodiments discussed herein. Therefore, it is intended that this invention be limited only by the claims and the equivalents thereof.

What is claimed is:

1. A system for calibrating an echo canceller using a preemptive tone sequence, comprising:
a node comprising a speaker, a microphone, and the echo canceller operatively connected to the microphone; and
a tone sequence management unit operatively connected to the node;
wherein the tone sequence management unit transmits a digital tone sequence to the speaker, wherein the speaker plays the digital tone sequence, wherein the microphone records an output of the speaker, converts the output into a digital data segment, and transmits the digital data segment to the echo canceller, and wherein the echo canceller is calibrated based on the digital data segment.

2. The system of claim 1, further comprising:
a second node operatively connected to the node and comprising a second speaker, a second microphone, and a second echo canceller operatively connected to the second microphone;
wherein the tone sequence management unit transmits the digital tone sequence to the second speaker, wherein the second speaker plays the digital tone sequence, wherein the second microphone records an output of the second speaker, converts the output of the second speaker into a second digital data segment, and transmits the second digital data segment to the second echo canceller, and wherein the second echo canceller is calibrated based on the second digital data segment.

3. The system of claim 2, wherein the node is geographically-dispersed from the second node.

4. The system of claim 1, wherein the tone sequence management unit is configured to communicate with the node over a network.

5. The system of claim 1, wherein the digital tone sequence comprises a plurality of polyphonic chimes.

6. The system of claim 1, wherein the digital tone sequence is arranged in an ascending order of frequency.

7. The system of claim 1, wherein the digital tone sequence covers a frequency range similar to the frequency range of a human voice.

8. The system of claim 1, wherein the digital tone sequence follows a chord progression.

9. The system of claim 1, wherein the speaker is positioned relative to the microphone in a configuration where microphone effectively records the output of the speaker.

10. The system of claim 1, wherein the microphone comprises a boundary microphone.

11. The system of claim 1, wherein the speaker and the microphone are encompassed within a speakerphone.

12. The system of claim 1, wherein the echo canceller is calibrated by comparing the digital data segment to the digital tone sequence to determine an echo.

13. The system of claim 1, wherein the node is at least a partially-enclosed room.

14. The system of claim 1, wherein the digital tone sequence serves as an indicator to a user.

15. The system of claim 14, wherein the digital tone sequence indicates to the user to begin speaking.

16. The system of claim 1, wherein the echo canceller initiates after receiving the digital data segment.

17. A method of calibrating an echo canceller using a preemptive tone sequence, comprising:
playing a digital tone sequence through a speaker to output an analog tone sequence;
recording the analog tone sequence;
converting the analog tone sequence to a digital data segment;
transmitting the digital data segment to an echo canceller; and
calibrating the echo canceller based on the digital data segment.

18. The method of claim 17, wherein calibrating the echo canceller based on the digital data segment comprises:
determining an echo by comparing the digital data segment and the digital tone sequence.

19. The method of claim 17, wherein the digital tone sequence comprises a plurality of polyphonic chimes.

20. The method of claim 17, wherein the digital tone sequence is arranged in an ascending order of frequency.

21. The method of claim 17, wherein the digital tone sequence covers a frequency range similar to the frequency range of a human voice.

22. The method of claim 17, wherein the digital tone sequence follows a chord progression.

23. The method of claim 17, wherein the digital tone sequence serves as an indicator to a user.

24. The method of claim 23, wherein the digital tone sequence indicates to the user to begin speaking.

25. The method of claim 17, wherein transmitting the digital data segment to an echo canceller comprises transmitting the digital data segment to the echo canceller to initiate the echo canceller.

26. A machine-readable medium having instructions stored thereon for execution by a processor to perform a method of calibrating an echo canceller using a preemptive tone sequence, the method comprising:
playing a digital tone sequence through a speaker to output an analog tone sequence;
recording the analog tone sequence;
converting the analog tone sequence to a digital data segment;
transmitting the digital data segment to an echo canceller; and
calibrating the echo canceller based on the digital data segment.
